(19) United States
(12) Patent Application Publication
(10) Pub. No.: US 2017/0076986 A1
(43) Pub. Date: Mar. 16, 2017

(54) NON-DESTRUCTIVE EPITAXIAL LIFT-OFF OF LARGE AREA III-V THIN-FILM GROWN BY METAL ORGANIC CHEMICAL VAPOR DEPOSITION AND SUBSTRATE REUSE

(71) Applicant: The Regents of the University of Michigan, Ann Arbor, MI (US)

(72) Inventors: Stephen R. Forrest, Ann Arbor, MI (US); Kyusang Lee, Ann Arbor, MI (US); Dejiu Fan, Ann Arbor, MI (US); Byungjun Lee, Ann Arbor, MI (US)

(73) Assignee: The Regents of the University of Michigan

(21) Appl. No.: 15/212,104

(22) Filed: Jul. 15, 2016

Related U.S. Application Data
(60) Provisional application No. 62/192,652, filed on Jul. 15, 2015.

(51) Int. Cl. H01L 21/78; C30B 33/02; C30B 33/10; C30B 33/12; C23F 1/16; C23F 4/00

(52) U.S. Cl. CPC H01L 21/7813; C23F 1/16; C23F 4/00; C30B 33/10; C30B 33/12; C30B 33/02; H01L 31/1896

(57) ABSTRACT

Disclosed are methods for preserving the integrity of large-sized growth substrates. The methods pertain to accelerating the rate of epitaxial liftoff, and improved cleaning and etching steps. Also disclosed are devices produced therein.

### CROSS-REFERENCE TO RELATED APPLICATION

This application claims the benefit of priority to U.S. Provisional Patent Application No. 62/192,652, filed on Jul. 15, 2015, which is incorporated by reference herein in its entirety.

### STATEMENT REGARDING FEDERALLY SPONSORED RESEARCH

This invention was made with government support under grant number W911NF-13-1-0485 awarded by the U.S. Army Research Laboratory's Army Research Office. The government has certain rights in the invention.

### JOINT RESEARCH AGREEMENT

The subject matter of this application was made by, on behalf of, and/or in connection with one or more of the following parties to a joint university-corporation research agreement: The Regents of the University of Michigan and NanoFlex Power Corporation. The agreement was in effect on and before the date the subject matter of this application was made, and such was made as a result of activities undertaken within the scope of the agreement.

The disclosure generally relates to methods of preserving the integrity of a growth substrate throughout epitaxial liftoff. Non-destructive epitaxial lift-off (ND-ELO) is a technology that can separate single crystalline III-V epitaxial layers from the growth substrate on which they are grown by selectively etching one or more sacrificial layers grown between the epitaxial layers and the growth substrate. The epitaxial layers are useful for making electrically active, optically active, solar, semiconductor and thin-film materials, such as photovoltaic (PV) devices.

In some instances, it may be desirable to transfer the epitaxial layers to host substrates that exhibit desirable optical, mechanical, or thermal properties. For example, Gallium Arsenide (GaAs) epilayers may be grown on Silicon (Si) substrates. However, the electronic quality of the resulting material may be insufficient for certain electronic applications. Therefore, it may be desirable to preserve the high material quality of the lattice-matched epilayers, while allowing the integration of those epilayers onto other substrates. This may be accomplished through ND-ELO, where the epitaxial layers may be “lifted off” and recombined (e.g., bonded or adhered) to a new host substrate. Thin-film devices can thus be fabricated on the transferred epitaxial layers. In conventional ELO processes, lifted-off layers are typically attached to flexible secondary handles using adhesives, such as thermal releasing tape, wax, or glue. These adhesives can be bulky, heavy, brittle, and subject to degradation while also requiring an additional transfer following the separation of the epitaxy onto an intermediate handle. To eliminate all use of adhesives and the necessity of an intermediate handle transfer, bonding processes that directly attach the epitaxial surface to the final flexible substrate following layer growth have been developed. For example, certain direct-attachment bonding processes have involved adding metal layers to adjoining surfaces of the active region and the flexible host substrate and using cold-welding to bond them.

The dominant epitaxial growth technology in industry is large area III-V thin-films grown by Metal-Organic Chemical Vapor Deposition (MOCVD). However, demonstrations of the ND-ELO process have been limited to 2-inch wafer size thin-films grown by molecular beam epitaxy (MBE). Application of the ND-ELO process to larger wafers is desirable as it enables the transfer of inorganic optoelectronic devices from their parent wafer to a secondary host substrate, while the parent wafer can be reused following lift-off of the active device region. By employing the method of ND-ELO, the recycled wafer can be recovered to its original epi-ready condition, which provides a high quality crystal plane for regrowth. The resultant wafer recycling leads to significant device manufacturing cost reductions by minimizing the consumption of expensive wafers.

The ND-ELO process, which enables transfer thin-film epitaxial layers from its parent substrate to a secondary host substrate, includes a step wherein the sacrificial layer is selectively etched. The growth substrate, after the removal of protection layers, can be recycled for regrowth. However, the long exposure time in HF during ELO, particularly for a large area wafer, can significantly damage and contaminate the protection layers due to limited etching selectivity of the etchant towards the sacrificial layer over the protection layers. For instance, during the etching steps, a GaAs protection layer may be slowly etched by HF, and arsenic oxides are formed on the top surface of the GaAs layer. Such contaminants may make the protection layers difficult to remove and can thereby lead to failure of wafer recycling. There is a need to develop advanced ND-ELO processes that are compatible with large-area wafers and MOCVD-based technology to preserve the integrity of growth substrates and improve the lateral etching rate to minimize the degradation of the surface of protection layers.

In some ELO procedures the cleaning steps include sonication. Sonication is a physical process which can dislodge particles from the wafers edge or other locations on the wafer. Additionally as the sonication is performed in solution additional particles may be present. the particles that are dislodged during the sonication are then scattered about the surface of the wafer which would then present locations for changes in etching rates. This would lead to progressively larger defects is additional etching steps are performed. There remains a need to reduce the amount of particles remaining after sonication steps.

Here, the present inventors introduce advanced ND-ELO methods that can be applied to lift-off of large area III-V thin-films, such as thin-films grown by MOCVD. The disclosed processes enable shorter lift off times and reduce damage to the protection layers caused by long exposure to HF acid. The advanced ND-ELO methods can be applied for large area and MOCVD grown epi-wafers as well as bulk processes without requiring the roller that is usually required for ELO processes to expedite the etching. For example, the disclosed methods can be applied to wafers larger than 2 inches in diameter, such at least about 4 inches, at least about 6 inches, or at least about 8 inches in diameter. In one embodiment, the methods are applied to wafers ranging from about 2 to about 8 inches in diameter. In another embodiment, the methods are applied to wafers ranging from about 3 to about 4 inches in diameter. In another embodiment, the methods are applied to wafers of about 4 inches in diameter. In some embodiments, the thin films are grown by MOCVD. The quality improvement of the parent wafer after ND-ELO is experimentally demonstrated by comparing the wafers with different lift-off times.

In one embodiment of the present disclosure, a method of preserving the surface of a growth substrate after epitaxial lift off, comprises the following steps: providing a growth structure comprising a growth substrate, a sacrificial layer located over the growth substrate, an epilayer located over the sacrificial layer, and at least two protection layers between the growth substrate and the sacrificial layer; lifting off the epilayer by etching the sacrificial layer; and removing the protection layers by etching.

In one embodiment of the present disclosure, a method of preserving the surface of a growth substrate after epitaxial lift off, comprises the following steps: providing a growth structure comprising a growth substrate, a sacrificial layer located over the growth substrate, an epilayer located over the sacrificial layer, and at least two protection layers between the growth substrate and the sacrificial layer; lifting off the epilayer by etching the sacrificial layer; removing at least one of the protection layers with an etchant; and removing at least one other protection layer with an etchant.

In one embodiment of the present disclosure, a method of preserving the surface of a growth substrate after epitaxial lift off, comprises the following steps: providing a growth structure comprising a growth substrate, a sacrificial layer located over the growth substrate, an epilayer located over the sacrificial layer, and at least two protection layers between the growth substrate and the sacrificial layer; lifting off the epilayer by etching the sacrificial layer; removing at least one of the protection layers with an etchant chosen from citric acid, H₂O₂, H₃PO₄, NH₄OH, H₂O and combinations thereof; and removing at least one other protection layer with an etchant chosen from HCl, H₃PO₄, H₂O and combinations thereof.

In one embodiment, the method may further comprise immersing the growth structure in solvent stripper after lifting off the epitaxial layer. In some embodiments, the solvent stripper is RemoverPG.

In one embodiment, removing one or more of the protection layers further comprises plasma etching.

In one embodiment, the sacrificial layer is etched by immersing the growth structure in an etchant, such as an acid solution, such as hydrofluoric acid (HF). In some embodiments where the sacrificial layer is wet etched, the etchant is agitated by stirring.

In another embodiment, the method further comprises performing rapid thermal annealing (RTA) on the growth structure subsequent to the lift-off step. In one embodiment, RTA is performed on the growth structure before removing any of the protection layers. In one embodiment, RTA is performed on the growth structure after the protection layers are removed. In one embodiment, RTA is performed on the growth substrate both before and after the protection layers are removed.

In another embodiment, the method further comprises the following steps after lifting off the epitaxial layer and before removing at least one of the protection layers: performing RTA on the growth structure; sonicating the growth structure; and immersing the growth structure in solvent stripper. In one embodiment, the method further comprises applying and removing an adhesive tape from the surface of the growth structure. In some embodiments, applying the removing an adhesive tape from the surface of the growth structure is performed after sonication.

In another embodiment, the growth structure further comprises a buffer layer located between the growth substrate and the protection layers. In some embodiments, the buffer layer comprises the same material as the growth substrate. For example, in some embodiments, the growth substrate and the buffer layer comprise GaAs.

In one embodiment, the protection layer nearest the growth substrate comprises InGaP. In one embodiment, the protection layer furthest from the growth substrate comprises GaAs. In one embodiment, the growth substrate comprises GaAs, the protection layer nearest the growth substrate comprises InGaP, and the protection layer furthest from the growth substrate comprises GaAs.

In another embodiment, the etchant for removing a GaAs protection layer is chosen from at least one of H₂O₂, H₃PO₄, NH₄OH, H₂O and combinations thereof. In one embodiment, the etchant for removing an InGaP protection layer is chosen from at least one of HCl, H₃PO₄, H₂O and combinations thereof.

Another aspect of the present invention is directed to a method of preserving the surface of a growth substrate, comprising providing a growth structure comprising a growth substrate and at least two protection layers located over the growth substrate; and removing the protection layers by etching.

In one embodiment, the method of preserving the surface of a growth substrate, comprises providing a growth structure comprising a growth substrate and at least two protection layers located over the growth substrate; removing at least one of the protection layers with an etchant chosen from citric acid, H₂O₂, H₃PO₄, NH₄OH, H₂O and combinations thereof; and removing at least one other protective layer with an etchant chosen from HCl, H₃PO₄, H₂O and combinations thereof.

In one embodiment, the method further comprises the following steps before removing at least one of the protection layers: performing RTA on the growth structure; sonicating the growth structure; and immersing the growth structure in solvent stripper. In one embodiment, the method further comprises applying and removing adhesive tape from the surface of the growth substrate, such as applying and removing adhesive tape after the sonication.

In one embodiment, the method further comprises the following steps before removing at least one of the protection layers: immersing the growth structure in solvent stripper; performing RTA on the growth structure; sonicating the growth structure; immersing the growth structure in solvent stripper, and performing another RTA on the growth structure. In one embodiment, the method further comprises applying and removing adhesive tape from the surface of the growth substrate, such as applying and removing adhesive tape after the sonication.

In one embodiment, at least one protection layer is removed with an ammonium-based etchant, such as NH₄OH or a solution thereof. In one embodiment, the protection layer located furthest from the growth substrate comprises GaAs and wherein removing the GaAs protection layer comprises etching with an ammonium-based etchant, such as an etchant comprising NH₄OH or a solution thereof. In one embodiment, removing the GaAs protection layer further comprises plasma etching.

In one embodiment, the protection layer located nearest the growth substrate comprises InGaP. In one embodiment, removing the InGaP protection layer comprises etching with an etchant that is not phosphoric acid based or that does not comprise phosphoric acid, such as HCl:H₂O. In one embodiment, removing the InGaP protection layer further comprises plasma etching.

In one embodiment, at least one of the protection layers comprises GaAs, wherein removing the GaAs protection layer comprises etching with NH₄OH:H₂O₂:H₂O. In one embodiment, at least one other protection layer comprises InGaP, wherein removing the InGaP protection layer comprises etching with HCl:H₃PO₄:H₂O or HCl:H₂O. In one embodiment, at least one of the protection layers comprises GaAs, wherein removing the GaAs protection layer comprises etching with citric acid: H₂O₂. In one embodiment, at least one other protection layer comprises InGaP, wherein removing the InGaP protection layer comprises etching with HCl:H₃PO₄:H₂O or HCl:H₂O.

In one embodiment, a method of preserving the surface of a growth substrate after epitaxial lift off, comprises the following steps: providing a growth structure comprising a growth substrate and at least two protection layers; removing at least one of the protection layers with an etchant chosen from citric acid, H₂O₂, H₃PO₄, NH₄OH, H₂O and combinations thereof; and removing at least one other protection layer with an etchant chosen from HCl, H₃PO₄, H₂O and combinations thereof.

In one embodiment, a method of preserving the surface of a growth substrate after epitaxial lift off, comprises the following steps: immersing the growth substrate in solvent stripper, placing the growth substrate through a RTA process (e.g., at 500° C. in N₂ for 1 minute), sonicating the growth substrate (e.g., in an acid solution such as in HF for 10 minutes), applying and removing an adhesive tape from the surface of the growth substrate, immersing the growth substrate in solvent stripper, placing the growth substrate through a RTA process (e.g., at 500° C. in N₂ for 1 minute), etching a protection layer comprising GaAs with plasma etching, etching the protection layer comprising GaAs with an etchant (such as an etchant comprising NH₄OH:H₂O₂:H₂O in the ratio of (2:1:10)), and etching a protection layer comprising InGaP with an etchant (such as an etchant comprising HCl:H₂O in the ratio of (3:1)).

### BRIEF DESCRIPTION OF FIGURES

FIGS. 1A and 1B. FIG. 1A shows a schematic of an epitaxial lift-off set-up with agitation using a magnetic stir bar. FIG. 1B shows a schematic of an epitaxial lift-off set-up with agitation using a magnetic stir bar and a top stirring rod.

FIGS. 2A and 2B. FIG. 2A shows a structure of an epitaxial lift-off process using stress materials on the back side of the sample to introduce compressive strain to the film. FIG. 2B shows a structure of an epitaxial lift-off process using stress materials on the back side of the sample to introduce tensile strain to the film.

FIGS. 3A, 3B, and 3C. FIG. 3A shows a photographic image and FIG. 3B shows a microscopic image of a quarter of a 4-inch wafer after 12 hours of ND-ELO process. Contaminations are generated on the wafer surface due to long exposure to HF acid. FIG. 3C shows a photographic image of lifted off thin film epitaxial layers transferred from the quarter wafer shown in FIG. 3A to a Kapton host substrate. Parts of the edge are peeled off from the Kapton substrate.

FIGS. 4A, 4B, and 4C. FIG. 4A shows a photographic image and FIG. 4B shows a microscopic image of a quarter of a 4 inch wafer after 8 hours of modified ND-ELO process with high speed agitation of HF etchant. No obvious contamination and damage are found on the wafer surface. FIG. 4C shows a photographic image of lifted off thin film epitaxial layers transferred from the quarter wafer shown in FIG. 4A to a Kapton host substrate. The edges are clearly identified without obvious peel-off.

FIGS. 5A and 5B. FIG. 5A shows an AFM image of the wafer surface right after lift-off, and FIG. 5B shows an AFM image of the wafer surface after GaAs layer plasma etch.

FIGS. 6A, 6B, 6C, and 6D. FIG. 6A shows an AFM image of the wafer surface after GaAs layer etch with H₃PO₄:H₂O₂:H₂O (3:1:25 ratio) etchant, FIG. 6B shows an AFM image of the wafer surface after In GaP layer etching with HCl:H₃PO₄ (3:1 ratio) etchant, FIG. 6C shows an AFM image of the wafer surface after dipping in NH₄OH:H₂O (1:1 ratio) for 60 s, and FIG. 6D shows an AFM image of the wafer surface after RTA process.

FIGS. 7A and 7B. FIG. 7A shows an AFM image of the wafer surface after GaAs etching with citric acid: H₂O₂ (4:1 ratio) etchant and InGaP plasma etch with (Cl₂ 15 sccm, Ar 9 sccm, 150 W TCP RF power, 15 s). FIG. 7B shows an AFM image of the wafer surface after InGaP layer etching with HCl:H₃PO₄:H₂O (1:1:1 ratio) etchant.

FIG. 8. An exemplary growth structure is shown. The growth structure comprises a growth substrate (e.g., a GaAs growth substrate), a buffer layer (e.g., a GaAs buffer layer), at least two protection layers (GaAs/InGaP protection layers), a sacrificial layer (e.g., AlAs) and an epitaxial layer.

FIGS. 9A, 9B, and 9C. Comparison between the surface roughness of wafers etched with H₃PO₄ versus NH₄OH. (ISJ 1 inch samples, ELO ˜5 hrs, RemoverPG overnight). FIG. 9A shows GaAs top layer etch with BCl3/Ar plasma. FIG. 9B shows GaAs top layer etch with H₃PO4:H₂O₂:H2O (3:1:25) etchant, 1 min 40 s. FIG. 9C shows GaAs top layer etch with NH₄OH:H₂O₂:H₂O (2:1:10), 30 s.

FIGS. 10A and 10B. Surface images of a phosphoric acid etched InGaP layer. (FIG. 10A shows GaAs top layer etch with Phosphoric acid, 30 s. FIG. 10B shows GaAs top layer etch with Phosphoric acid, 60 s.)

FIG. 11. Image of adhesive applied to surface wafer after ELO.

As used herein, the term “layer” refers to a member or component of a photosensitive device whose primary dimension is X-Y, i.e., along its length and width, and is typically perpendicular to the plane of incidence of the illumination. It should be understood that the term “layer” is not necessarily limited to single layers or sheets of materials. A layer can comprise laminates or combinations of several sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, the term “III-V material” may be used to refer to compound crystals containing elements from group IIIA and group VA of the periodic table. More specifically, the term III-V material may be used herein to refer to compounds which are combinations of the group of Gallium (Ga), Indium (In) and Aluminum (Al), and the group of Arsenic (As), Phosphorous (P), Nitrogen (N), and Antimony (Sb). Representative materials may include GaAs, InP, InGaAs, AlAs, AlGaAs, InGaAsP, InGaAsPN, GaN, InGaN, InGaP, GaSb, GaAlSb, InGaTeP, and InSb and all related compounds. The term “Group IV” comprises such semiconductors as Si and Ge in column IVA of the periodic chart. Group II-VI comprises such semiconductors as CdS and CdTe, for example, that reside in Groups HA and VIA of the periodic chart.

As used herein, the expression “disposed on,” “located over,” and the like permits other materials or layers to exist between a material being disposed and the material on or over which it is disposed. Likewise, the expression “bonded to” permits other materials or layers to exist between a material being bonded and the material to which it is bonded.

As used herein, a straining layer that induces a curvature of a handle toward a growth substrate means that the straining layer induces the handle to take a concave shape from the point of reference of the growth substrate.

As used herein, a straining layer that induces a curvature of a handle away from a growth substrate means that the straining layer induces the handle to take a convex shape from the point of reference of the growth substrate.

The term “strain” as used herein can be defined in terms of the residual strain in the deposited layer. The strain can be tensile, compressive or near-neutral. A tensile strain will curve the handle towards the straining layer, a compressive strain will curve the handle away from the straining layer, and a near-neutral strain will not cause any significant curvature to the handle. In one embodiment, the strain applied to a handle material is tensile which accelerates curvature of the handle towards a wafer.

The thin film devices described herein may be photosensitive devices. In some embodiments, the thin film devices described herein are solar cell devices.

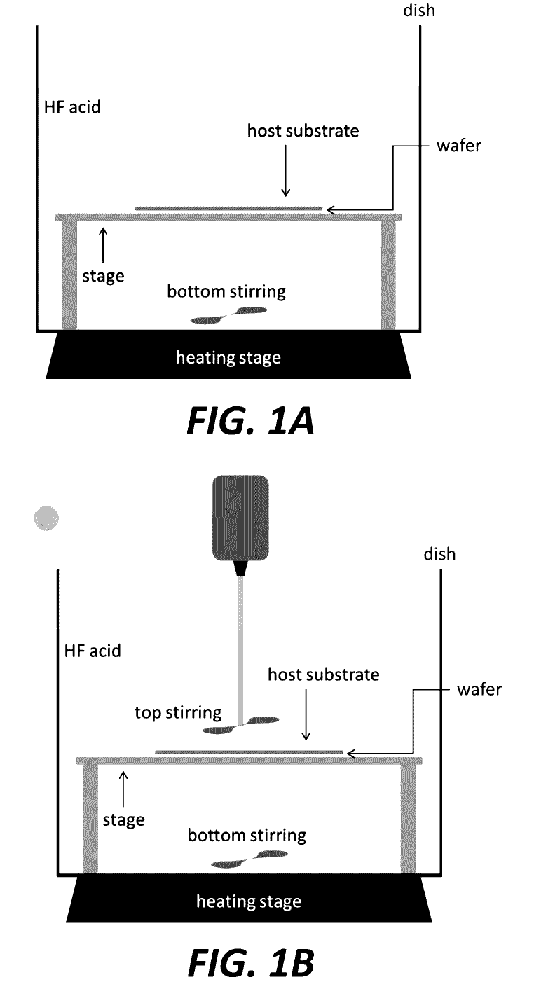

In one aspect of the present disclosure, an advanced ND-ELO process is disclosed wherein the etching of the sacrificial layer during ND-ELO process is accelerated and the lift-off time is reduced by using high speed agitation of the HF etchant, such as by using a magnetic stirring bar, while the etchant is heated (FIG. 1(a)). In one embodiment, a growth substrate may be recovered after epitaxial growth by first evaporating Ir on a host substrate. Then, Au may be coated on both the growth structure and the host substrate. Next bonding of the host substrate to the epilayer and then etching of the sacrificial layer may be performed either sequentially or in a combined process. During the etching of the sacrificial layer, the magnetic bar stirring speed may be increased from 400 rpm to a higher speed (for example, 800 rpm). In some embodiments, the magnetic bar stirring speed may be from 600 rpm to 1000 rpm. In some embodiments, the magnetic bar stirring speed may be from 700 rpm to 900 rpm. In some embodiments, an additional stirring apparatus may be added to the etchant to increase the agitation of the etchant solution. After immersion in the etchant solution, the lift-off time may be monitored and the lifted off thin film epitaxial layers and the parent wafer are checked under microscope. It has been observed that the lift-off time was reduced from 12 hours to 8 hours by agitating the HF etchant at higher speeds. Without being bound to a single theory of operation, the agitation may help the HF etchant to effectively diffuse into the etching interface. The time for etching the sacrificial layer to achieve lift off of the epilayer may be further reduced by introducing additional stirring bars to more efficiently create the flow of etchant (FIG. 1(b)).

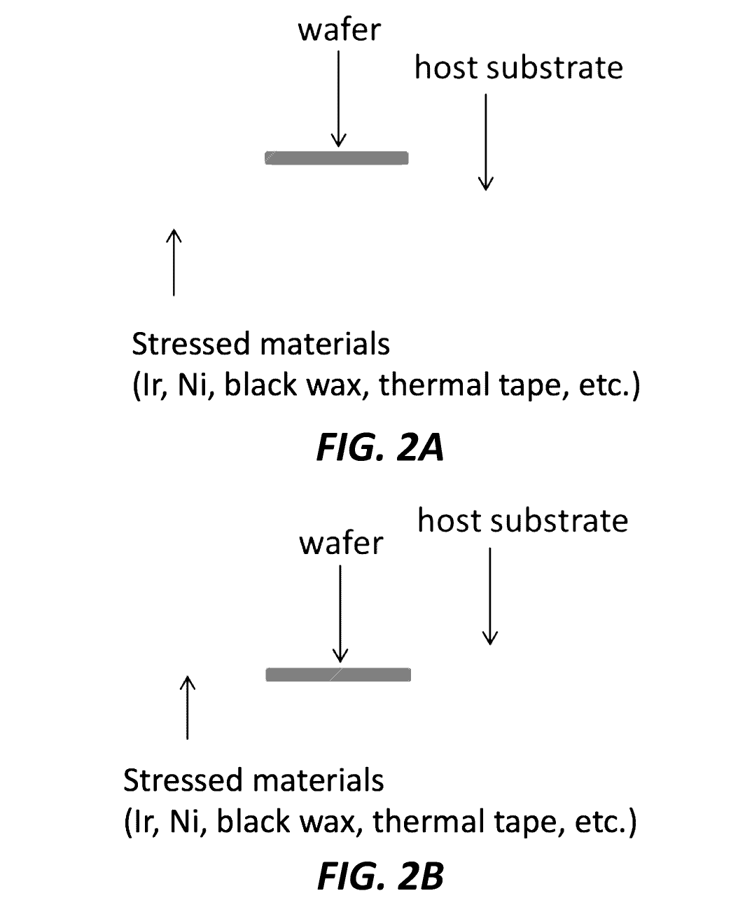

Another aspect of the present disclosure is directed to accelerating the lift-off process by inducing curvature to the host substrate by attaching stressed material on the back side of the host substrate after wafer bonding process (FIGS. 2(a) and (b)). After epitaxial growth of the protection layers, sacrificial layers and epilayers, Ir may be evaporated on a host substrate. Then, Au may be coated on both the growth structure and the host substrate. Then bonding is performed between the growth structure and the host substrate. Then, polymer with a different coefficient of thermal expansion (including non-limiting examples such as PVDF, and thermal tape) may be applied to the back side of host substrate. In another embodiment, Ir, Ni or similar acceptable materials can be sputtered on the back side of the host substrate. In yet another embodiment, black wax may be spin/drop-casted or melted on the back side of the host substrate. Curvature, which will accelerate the following ELO process, may be induced during the ELO process by applying one or more of these methods which do not require a roller. Following one of these steps, the entire sample may then be dipped in HF to etch the sacrificial layer during the ND-ELO process. After the etching of the sacrificial layer during the ELO process, a stressed material on the back side of sample, if present, can be removed.

Another aspect of the present disclosure is directed to methods of removing the protection layers from the growth substrate such that large size growth substrates (i.e. wafers) may be recycled.

In one embodiment, at least first and second protective layers, such as a scheme of InGaP/GaAs protections layers, may be grown between the growth substrate and a sacrificial layer, such as AlAs. The protection layers serve to protect the growth substrate from being damaged during ND-ELO. In one embodiment, a buffer layer is grown on top of the growth substrate (a parent GaAs wafer). For example, if the growth substrate comprises GaAs, a GaAs buffer layer may growth on the surface of the GaAs growth substrate.

In a particular embodiment, a GaAs buffer layer is grown on a GaAs growth substrate. After growth of the buffer layer, an InGaP protection layer is grown (e.g., 100 nm thick lattice matched). Then, a GaAs layer as a second protective layer (e.g., 500 nm thick) is grown on top of the InGaP layer. During the ELO process, the GaAs layer protective layer protects the GaAs growth substrate. After ELO, the surface quality of the parent GaAs wafer is recovered by removing the top GaAs and InGaP protection layers, thereby reaching an atomically flat GaAs buffer layer that is suitable for wafer reuse. Other embodiments may contain different materials, additional protective layers, and/or different ordering of layers as would be understood by those of skill in the art.

During the ELO process, the top GaAs layer may be slowly etched by HF, which may lead to arsenic oxides forming on the top surface of the GaAs layer. After etching of the sacrificial layer, the growth substrate and protection layers may be dipped into a solvent stripper for a period of time, such as for at least 10 minutes, 30 minutes, 1 hour, 3 hours, 6 hours, 12 hours, or more in order to prevent the formation of arsenic oxides which makes recovery of parent wafer surface difficult. In one embodiment, the solvent stripper is Remover PG. In one embodiment, the solvent stripper is Remover PG and the growth substrate and protection layers are immersed in the solution for a period of 12 hours at 80° C.

In some embodiments a buffer layer may be grown between the parent wafer and the sacrificial layer.

In one embodiment, the growth substrate may be protected by one protection layer. In another embodiment the growth substrate may be protected by two protection layers. In one embodiment, at least one of the protection layers is chosen from a InGaP layer and a GaAs layer. The protection layers may be removed through chemical etching, plasma etching or a combination of both. Generally the protection layers may be etched by any etchant that have selectivity between the protection layer and the underlying layer. In some embodiments, where the protection layers are InGaP and GaAs, the etchants for the InGaP may be HCl:H₂O (e.g., 1:1 ratio) or HCl:H₃PO₄ (e.g., 3:1 ratio) or HCl:H₃PO₄:H₂O (e.g., 1:1:1 ratio), and the etchants for the GaAs layer may be H₃PO₄:H₂O₂:H₂O (e.g. 3:1:25 ratio) or NH₄OH:H₂O₂:H₂O (e.g. 2:1:10 ratio). In some embodiments, HCl:H₃PO ₄:H₂O (e.g., 1:1:1 ratio) may be used to minimize the risk of overetching the layer underlying the GaAs protection layer, as this etchant has a slower etching rate. Typical root mean square (RMS) roughness between 0.2 nm-0.3 nm has been observed after InGaP protection layer etching. Before etching the InGaP layer, plasma etching InGaP (e.g., Cl₂ 15 sccm, Ar 9 sccm, 150 W TCP RF power, 15 s) can be done for cleaning the InGaP surface after GaAs wet etching.

For large sized wafers, after epilayer is lifted off by etching the sacrificial layer, more etching residues remain on the topmost surface of the protective layer and may hinder or prevent recovery of the growth substrate. This problem can be solved by chemically assisted physical etching of the topmost surface of the protective layers using plasma etching. In one example, GaAs is used as the top protection layer, and the method is exemplified by placing the wafer in BHF for 90 s to remove native oxides forming on the top surface. Then the top GaAs layer may be etched 200 nm via plasma etching. For example, the plasma etching conditions may be: (BCl₃ 12 sccm, Ar 40 sccm, 300 W TCP RF power, 50 s). After BHF cleaning and plasma etching, the remaining GaAs protection layer can be removed using one or more wet etchants that has selectivity between GaAs and InGaP. This may be done with citric acid: H₂O₂ (e.g., 4:1 ratio) etchant or H₃PO₄:H₂O₂:H₂O (e.g., 3:1:25 ratio) etchant, etc. Due to the fact that these etchants have etching selectivity between the GaAs and InGaP protection layers, the top GaAs surface can be etched away, leaving the InGaP protection layer and growth substrate. While etching the GaAs protection layer, exposure of an InGaP protection layer and the like to phosphoric acid based etchant can result in the formation of island-like residue. The present inventors have discovered that etching the GaAs protection layer with an ammonium-based etchant, e.g., NH₄OH:H₂O₂:H₂O, can prevent the formation of such residues. Thus, in some embodiments of the present disclosure, at least one of the protection layers is etched with an ammonium-based etchant. In certain embodiments, the etchant comprises NH₄OH.

Depending on the original growth condition, phosphor residues might remain on final surface of the restored growth substrate. These problems can be mitigated by dipping the wafer in dilute NH₄OH, which are used to passivate the GaAs surfaces of either the growth substrate or the GaAs protection layer. After dipping in NH₄OH, residues can be removed by rapid thermal annealing (RTA), or directly placed in to the growth chamber, applying heat with group V gas flow.

An aspect of the present invention is directed minimizing the amount of particles on the surface of the growth substrate after the ELO process. In one embodiment, methods for preserving the growth substrate comprise placing the growth substrate and protection layers in remover PG for 8 hours after ELO and then subjecting the growth substrate to RTA. Then, the growth substrate may be sonicated, e.g., in HF:H2O (e.g., 1:2) solution, such as for 10 mins. In one embodiment, tape is used to remove any gold on the edge of the growth substrate or any particles generated during sonication. In an embodiment, the top GaAs protection layer may be etched with NH₄OH:H₂O₂:H₂O (e.g., 2:1:10) solution is used for fast etch rate and uniformity.

Etching steps that take a long time generally introduce a large variability in the height and roughness of the underlying layer as different regions may etch at different rates. Due to the fact that etching the GaAs top protection layer may take a longer time, some InGaP layer might be exposed at different locations after a long time in a GaAs etchant. This problem can be alleviated by using a NH₄OH based etchant instead of a H₃PO₄ etchant. Some samples show nano-scale islands when the InGaP layer is exposed to a phosphoric acid based etchant for a long time; however, this problem can be prevented by the InGaP layer being etched through the GaAs protection layer or by using a different type of etchant. In one embodiment the InGaP layer may be etched by sonicating the growth substrate in HCl:H₂O (e.g., 3:1) solution (to prevent bottom GaAs buffer layer from being etched by phosphoric acid. In other embodiments the GaAs protection layer may be wet etched by HCl:H3PO4 (e.g., 3:1) solution).

One aspect of the present invention is directed to methods of preserving the surface of a growth substrate, the growth substrate comprising at least two protection layers, the method comprising: immersing the growth substrate in solvent stripper, removing at least one of the protection layers with an etchant chosen from citric acid, H₂O₂, H₃PO₄, NH₄OH, H₂O and combinations thereof, and removing at least one other protective layer with an etchant chosen from HCl, H₃PO₄, H₂O and combinations thereof. In one embodiment, the method further comprises at least one of rapid thermal annealing (RTA), sonication of the growth substrate in HF etchant, application and removal of an adhesive tape, and additional immersion in a solvent stripper. As each additional etching step may allow for additional impurities to migrate to the surface of the wafer, additional solvent stripper immersion steps may be employed. In one embodiment, the solvent stripper may be RemoverPG.

Another aspect of the present invention is directed to methods of preserving the surface of a growth substrate, the method comprising the following steps: immersion of the growth substrate and the protection layers in solvent stripper, performing RTA (e.g., 500° C. in N₂ for 1 minute) on the growth substrate, sonicating the growth substrate in HF (e.g., for 10 minutes), applying and removing an adhesive tape such that any particles or leftover deposited metal that may adhere to the tape is also removed, immersion of the growth substrate and protection layers in solvent stripper, performing RTA (e.g., 500° C. in N₂ for 1 minute) on the growth substrate, etching a protection layer comprising GaAs with plasma etching, etching the protection layer comprising GaAs with an etchant comprising NH₄OH:H₂O₂:H₂O (e.g., 2:1:10 ratio), and etching a protection layer comprising InGaP with an etchant comprising HCl:H₂O (e.g., 3:1 ratio).

Aspects of the present invention are directed to methods of preserving the growth substrate wherein the liftoff time of the sacrificial layer has been accelerated. The ND-ELO and cleaning methods described herein are not limited to any particular growth structure or growth substrate and are suitable for use on a variety of growth structures or growth substrates. U.S. Pat. No. 8,378,385 and U.S. Patent Publication No. 2013/0043214 are hereby incorporated by reference for their disclosure of growth structures and materials, for example, a growth structure comprising a growth substrate, protection layers, a sacrificial layer, and an epilayer.

In one embodiment of the present disclosure, a thin film device for epitaxial lift off comprises a handle and one or more straining layers disposed on the handle, wherein the one or more straining layers induce a curvature of the handle.

In another embodiment, a thin film device and recoverable growth substrate for epitaxial lift off comprises a growth substrate, a handle, and one or more straining layers disposed on at least one of the growth substrate and the handle, wherein the handle optionally having the one or more straining layers disposed thereon is bonded to the growth substrate, and wherein the one or more straining layers induce at least one strain on the handle chosen from tensile strain, compressive strain and near-neutral strain.

In another embodiment, thin film devices for epitaxial lift off comprise an epilayer disposed on a growth substrate, a handle, and one or more straining layers disposed on at least one of the growth substrate and the handle, wherein the handle optionally having the one or more straining layers disposed thereon is bonded to the growth substrate, and wherein the one or more straining layers induce at least one strain on at least one of the handle and epilayer chosen from tensile strain, compressive strain, and near-neutral strain. In some embodiments, the one or more straining layers induce at least one strain on the handle and the epilayer.

In another embodiment, a straining layer comprises a metal. Suitable examples of this metal include pure metals such as Gold, Nickel, Silver, Copper, Tungsten, Platinum, Palladium, Tantalum, Molybdenum, or Chromium, or metal alloys containing Iridium, Gold, Silver, Copper, Tungsten, Platinum, Palladium, Tantalum, Molybdenum, and/or Chromium. In yet another embodiment, the thickness of the straining layer ranges from about 0.1 nm to about 10000 nm.

In some embodiments, the straining layer induces curvature of a handle. In some embodiments, the one or more straining layers induce curvature of the handle upon etching the sacrificial layer. In some embodiments, the one or more straining layers induce curvature of the handle upon parting with the growth substrate. In some embodiments, the curvature of the handle is toward a growth substrate. In some embodiments, the straining layer induces a curvature of the handle away from a growth substrate. In some embodiments, the straining layer minimizes curvature of the handle.

In one embodiment, a method of fabricating a thin film device for epitaxial lift off comprises, depositing one or more straining layers on a handle, wherein the one or more straining layers induce at least one strain on the handle chosen from tensile strain, compressive strain and near-neutral strain. In some embodiments, the method can induce a curvature of the handle.

In another embodiment, a straining layer induces tensile strain to induce a curvature of the handle towards a growth substrate.

In one embodiment, a method of fabricating a thin film device for epitaxial lift off comprises, providing a growth substrate and a handle, depositing one or more straining layers on at least one of the growth substrate and the handle, and bonding the handle optionally having the one or more straining layers disposed thereon to the growth substrate.

In yet another embodiment, a method for epitaxial lift off comprises, depositing an epilayer over a sacrificial layer disposed on a growth substrate; depositing one or more straining layers on at least one of the growth substrate and a handle; bonding the handle to the growth substrate; and etching the sacrificial layer.

A further embodiment of the present disclosure is directed to a thin film solar cell device comprising at least one layer disposed on a growth substrate that is bonded to a handle, wherein the handle is both sufficiently flexible and has a curvature that expedites epitaxial lift off. Another embodiment of the present disclosure is directed to a thin film solar cell device comprising at least one layer disposed on a growth substrate that is bonded to a handle, wherein a difference in coefficient of thermal expansion between the wafer and handle is used to create a curvature in the handle to expedite epitaxial lift off.

The present disclosure further relates to removal of contaminants caused by the ELO process by performing RTA on the growth structure after epitaxial lift off. In some embodiments, RTA is performed before etching the protection layers. In some embodiments, RTA is performed after etching the protection layers. In some embodiments, RTA is performed before and after etching the protection layers. In some embodiments, RTA that is performed before etching the protection layers at least partially decomposes the protection layer surface.

In yet another embodiment, the temperature and/or rate at which the straining layer deposition is performed is varied to induce different strains.

Suitable examples of materials comprising the handle include materials such as polyimide, e.g., Kapton®, polyethylene, polyethylene glycol (PEG), polyethylene terephthalate (PET), polyethylene terephthalate glycol (PET-g), polystyrene, polypropylene, polytetrafluoroethylene (PTFE), e.g. Teflon®, polyvinylidene difluoride and other various partially fluorinated polymers, nylon, polyvinyl chloride, chlorosulfonated polyethylene (CSPE), e.g., Hypalon®, and Poly(p-phenylene sulfide).

Suitable examples of materials comprising the handle also include metal foils such as stainless steel, copper, molybdenum, tantalum, nickel and nickel alloys, e.g., Hastelloy®, bronze, gold, noble metal coated foils, and polymer coated foils.

In some embodiments, the handle material is flexible, not confined, and is free to deform and bend during the ELO process.

The growth substrate may comprise any number of materials, including single crystal wafer materials. In some embodiments, the growth substrate may be chosen from materials that include, but are not limited to, Ge, Si, GaAs, InP, GaN, AlN, GaSb, InSb, InAs, SiC, CdTe, sapphire, and combinations thereof. In some embodiments, the growth substrate comprises GaAs, such as a single-crystalline GaAs wafer. In some embodiments, the growth substrate comprises InP. In some embodiments, the materials comprising the growth substrate may be doped. Suitable dopants may include, but are not limited to, Zinc (Zn), Mg (and other group IIA compounds), Zn, Cd, Hg, C, Si, Ge, Sn, O, S, Se, Te, Fe, and Cr. For example, growth substrate may comprise InP doped with Zn and/or S.

The epilayer or epitaxial layer as described herein may refer to any active layer or collection of active layers. The epilayer or epitaxial layer may include, for example, any active material that is desirable for use in a photosensitive device, such as a photovoltaic device. Thus, in some embodiments, the epilayer or epitaxial layer may be considered a “device region.” In some embodiments, the epilayer or epitaxial layer comprises at least one III-V material.

In one embodiment, the present disclosure provides a method of fabricating a thin film device for epitaxial lift off comprising, providing a growth substrate and a handle, depositing one or more straining layers on at least one of the growth substrate and the handle, and bonding the handle optionally having the one or more straining layers disposed thereon to the growth substrate. In some embodiments, one or more straining layers are deposited on the growth substrate and the handle. In some embodiments, the growth substrate has an epilayer disposed thereon. In some embodiments, the growth substrate has a sacrificial layer and an epilayer disposed thereon. In some embodiments, the epilayer is disposed on the sacrificial layer.

In yet another embodiment, the present disclosure provides a method for epitaxial lift off comprising, depositing an epitaxial layer over a sacrificial layer disposed on a growth substrate; depositing one or more straining layers on at least one of the growth substrate and a handle; bonding the handle to the wafer; and etching the sacrificial layer. In some embodiments, one or more straining layers are deposited on the growth substrate and the handle. In certain embodiments, the sacrificial layer can be etched with hydrogen fluoride.

In some embodiments, bonding the handle to the growth substrate is performed by a cold welding process.

Materials and layers may be deposited in accordance with techniques known in the art.

### EXAMPLES

The present disclosure will now be described in greater detail by the following non-limiting examples. It is understood that the skilled artisan will envision additional embodiments consistent with the disclosure provided herein.

To demonstrate the effectiveness of the modified ND-ELO method for large area lift-off, the following exemplary experiments were performed using methods described above on quarter of a 4 inch wafer. As a demonstration of the effectiveness of said methods the lift-off time was tracked and the quality of the lifted off thin film epitaxial layers and the parent wafer was evaluated under microscope.

The experiment was performed as follows. The epitaxial III-V active layers were grown by metal organic chemical vapor deposition (MOCVD) on a 4 inch semi-insulating GaAs substrate. The growth structure comprises a GaAs buffer layer, 100 nm InGaP/500 nm GaAs epitaxial protection layers, followed by a 25 nm thick AlAs sacrificial layer. Next, an inverted GaAs solar cell structure was grown. After growth, a 5 nm thick Ir adhesion layer was evaporated on a 25 micron thick Kapton host substrate. Then the grown epitaxial wafer was dipped in buffered HF for 90 s to remove the surface oxide. Next, 200 nm thick Au films were then deposited on both the grown epitaxial wafer and the Kapton host substrate. After Au deposition, the 4 inch epitaxial wafer was cleaved into 4 pieces of quarter wafer. The two opposing Au surface were then bonded together with the application of heat and pressure. Using an EVG 520 wafer bonder under −10−5 torr vacuum, 7.4 MPa of pressure was applied to establish a bond between the two gold films with a 5000 N/sec ramping rate. The temperature was ramped at 45° C./min to 200° C., and holding at the peak temperature for 6 min. To apply a uniform force over the sample area, a soft graphite sheet was inserted between the sample and the press head.

Once the epi-sample was bonded to the Kapton substrate, the thin film active device epitaxial layers was removed from its parent GaAs substrate through the ELO process. The entire sample was immersed in a 16.7% HF acid maintained at 60° C. The HF acid was agitated with a stir bar at 800 rpm. Due to the high etch selectivity between AlAs and the active compound semiconductor layers, dilute HF removed the 25 nm thick AlAs sacrificial layer between the wafer and active device epitaxial layers without etching the adjacent layers.

A control sample was prepared following the conditions described above except that the Ir adhesion layer thick was 10 nm and the stirring speed in HF acid was 400 rpm.

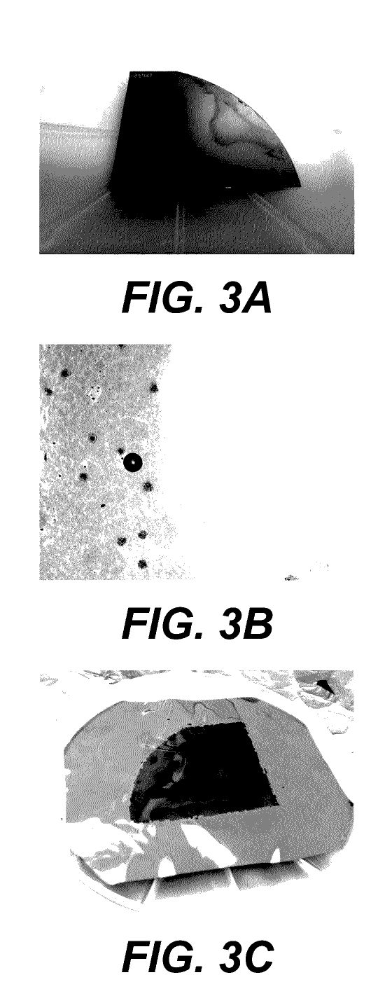

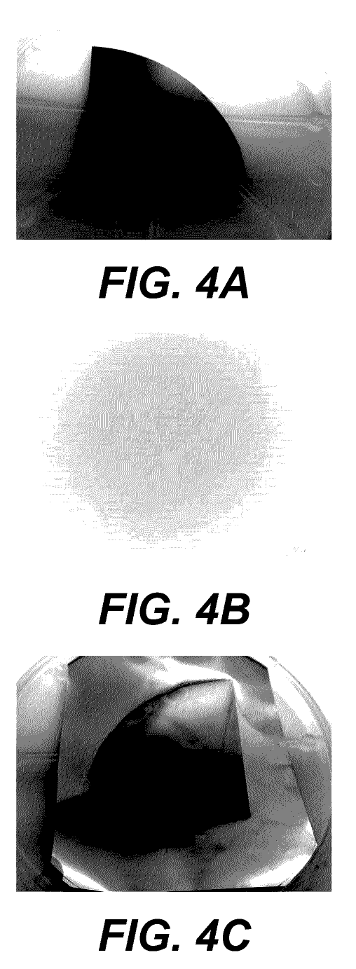

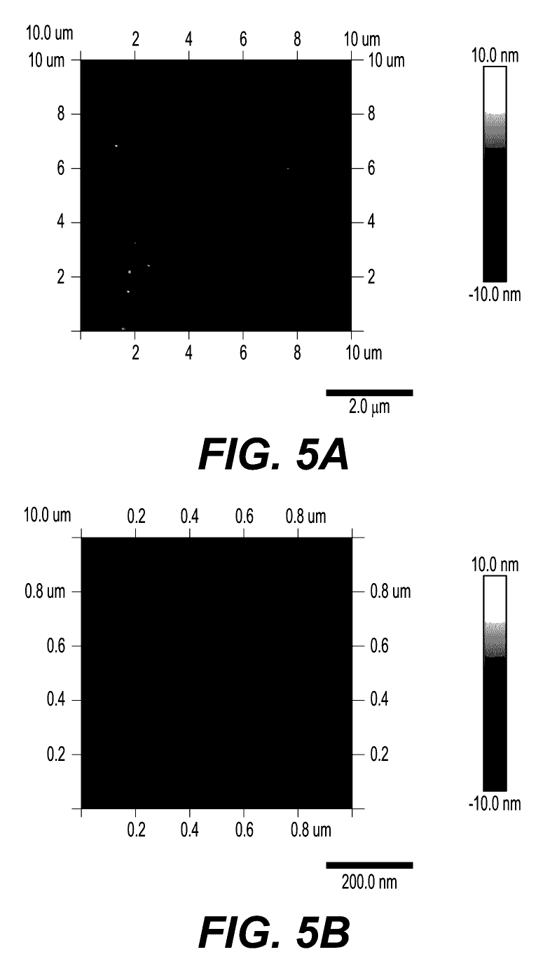

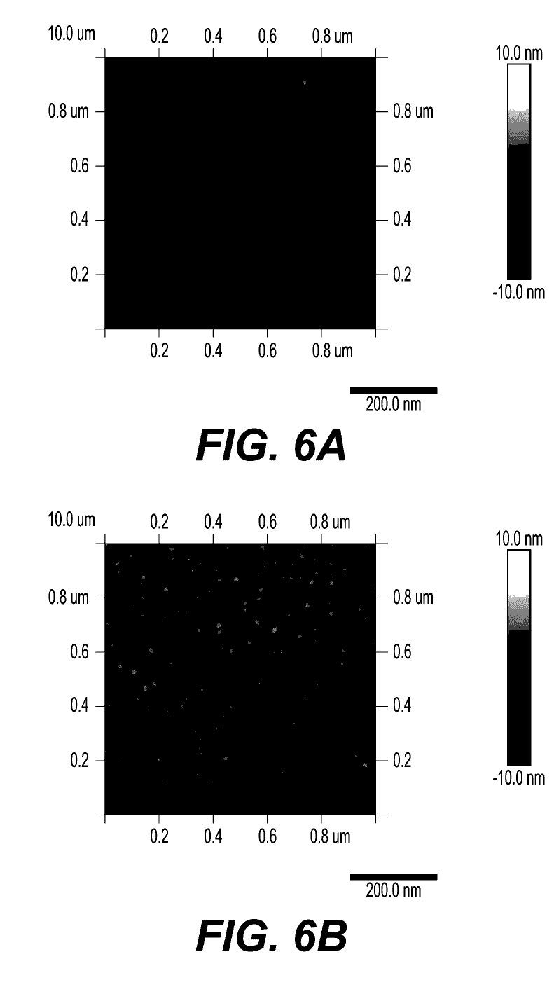

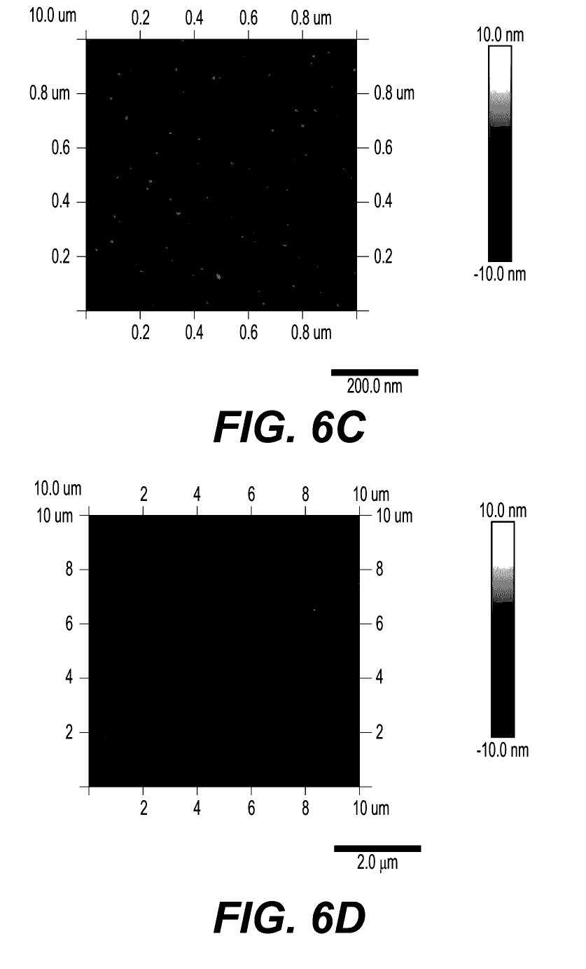

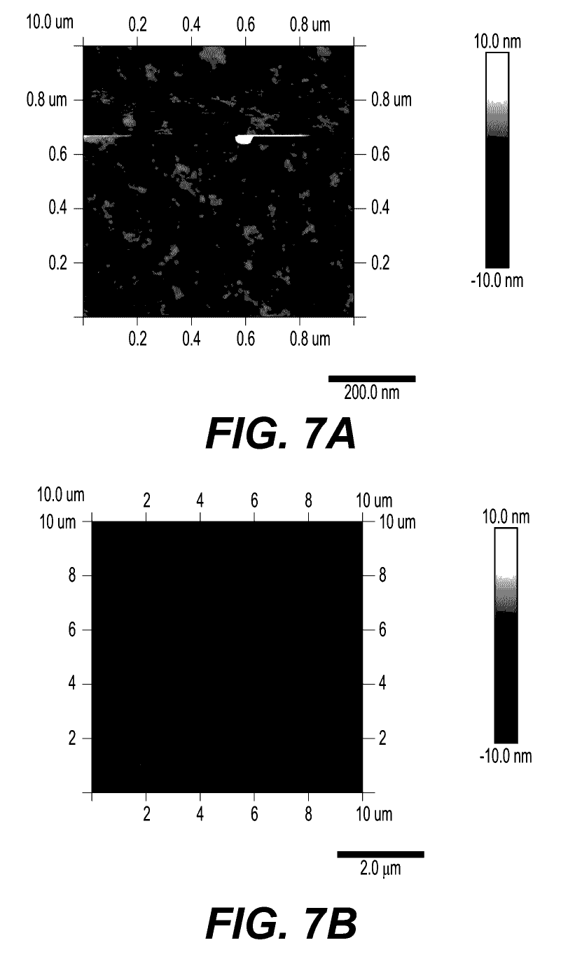

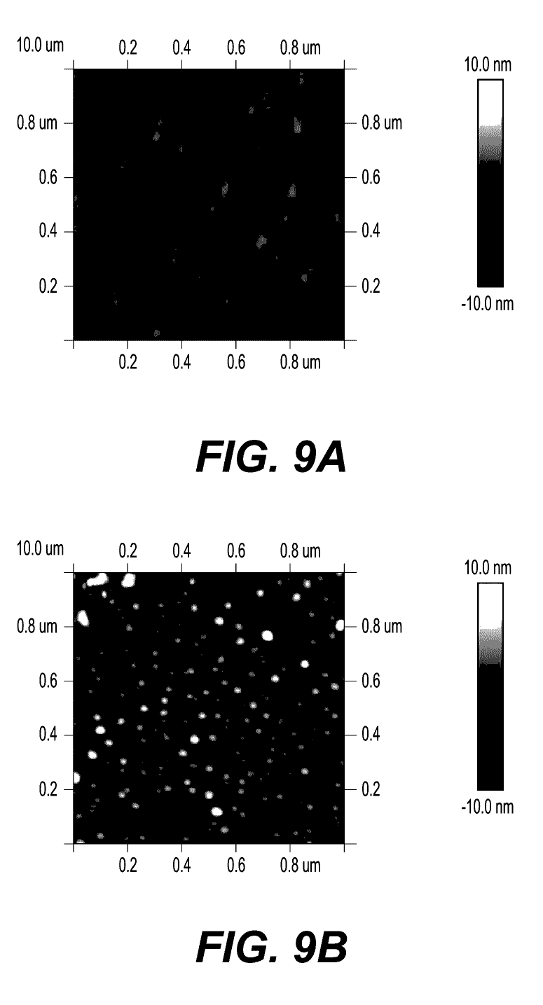

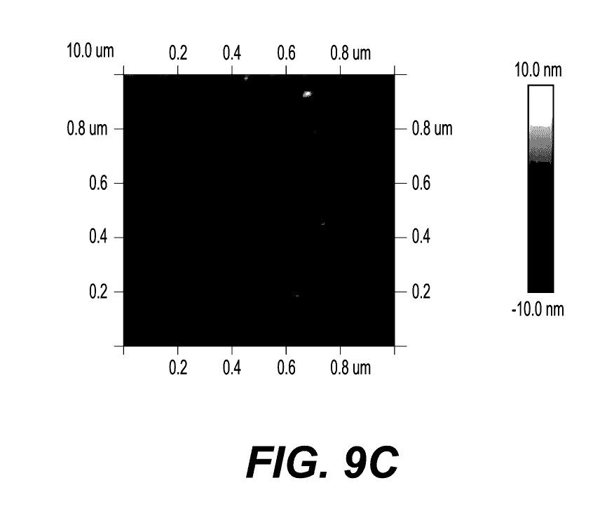

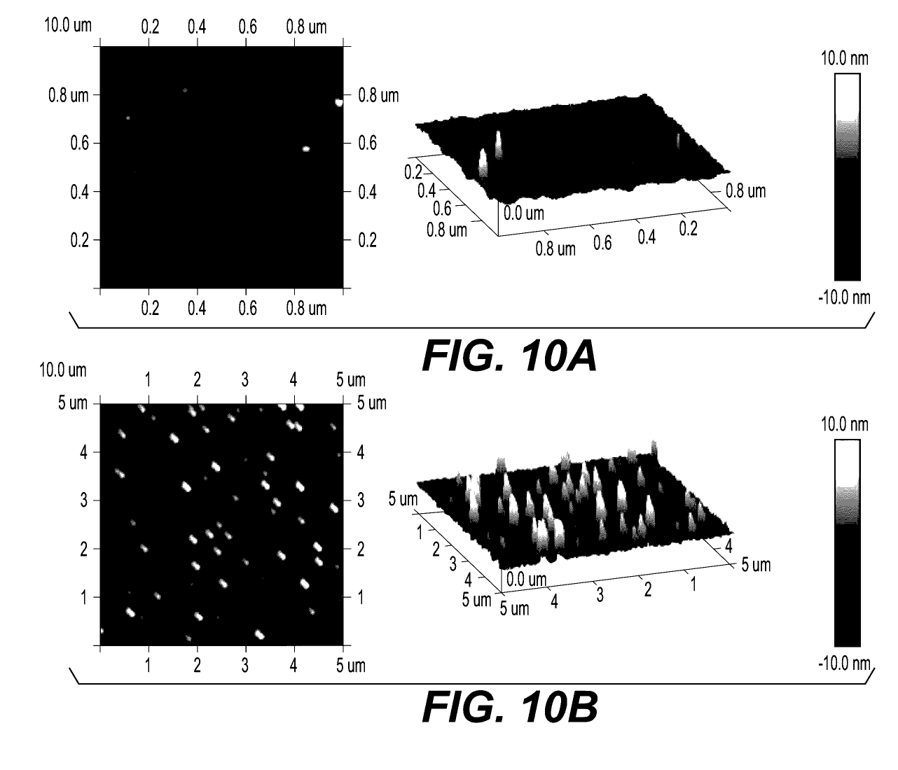

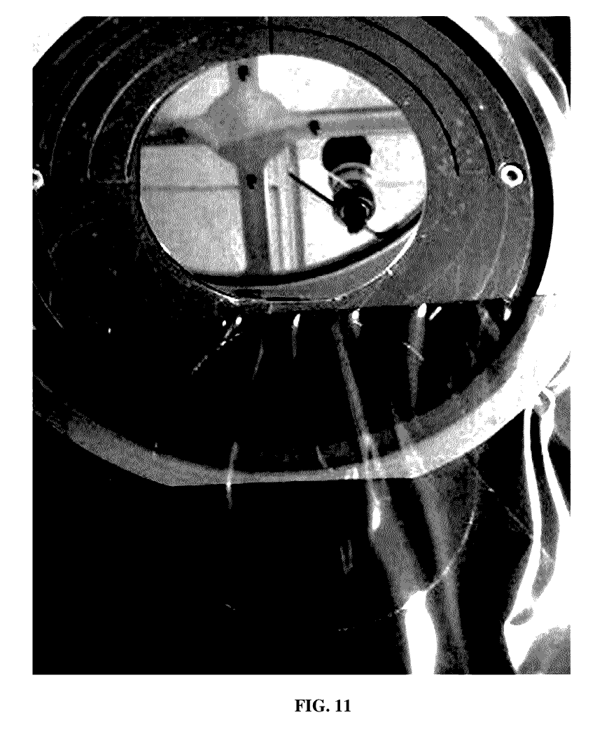

FIGS. 3 (a) and (b) show the damaged and contaminated wafer surface after 12 hours of lift-off. The edge peel-off occurs on the transferred epitaxial layers as shown in FIG. 3(c). Using the modified ND-ELO method with high agitation speed, the quarter of a 4-inch wafer was lifted off after 8 hours. FIGS. 4 (a) and (b) show the undamaged wafer surface. No edge peel-off occurs on the transferred epitaxial layers as shown in FIG. 4 (c).

To demonstrate the effectiveness of protection layer, measurements were performed on each step of protection layer removal process. The surface quality was checked by measuring RMS roughness with atomic force microscope.

During etching of GaAs layer, different GaAs wet etchants (citric acid: H₂O₂ (4:1 ratio) etchant and H₃PO₄:H₂O₂:H₂O (3:1:25 ratio) etchant) are used to show that both etchants can be used to etch GaAs layer. Also during InGaP layer etching, different In GaP etchants (HCl:H₃PO₄ (3:1 ratio), HCl:H₃PO₄:H₂O (1:1:1 ratio)) were used. For both processes with and without RTA, the BHF cleaning and GaAs plasma etch process steps may be the same. RMS roughness is both 0.3 nm after ELO and after plasma clean. Surface roughness image after lift-off is shown on FIG. 1(a), and surface after plasma clean is shown in FIG. 1(b).

Three exemplary methods were performed to recover the parent wafer after ELO. Two used an RTA process, and the third did not.

For the first exemplary RTA process, the GaAs layer was etched with H₃PO₄:H₂O₂:H₂O (3:1:25 ratio) etchant for 100 seconds, and RMS roughness is 0.4 nm. The surface is shown on FIG. 2(a). After GaAs layer etching, InGaP layer was etched using HCl:H₃PO₄ (3:1 ratio) etchant for 130 seconds, and RMS roughness was 0.7 nm. The surface after InGaP layer etching is shown in FIG. 2(b). After InGaP layer etching, the remaining phosphor residues were reduced by dipping the sample in NH₄OH:H₂O (1:1 ratio) for 60 seconds, and RMS roughness was 0.4 nm. The surface after immersion in NH₄OH is shown in FIG. 2(c). Any remaining small residues were removed with an RTA process at 430° C. with nitrogen gas for 60 seconds, which left the surface with RMS roughness 0.3 nm. FIG. 2(d) shows the surface of after the RTA process.

For the second technique using RTA, before a plasma etch of GaAs, RTA was performed at 500° C., in N₂, for 1 minute. Then, the GaAs layer was etched with a NH₄OH:H₂O₂:H₂O (2:1:10 ratio) etchant for 30 seconds. After the GaAs etching, the InGaP layer was directly etched with HCl:H₂O (3:1) ratio etchant using sonication, for 30 seconds, leaving smooth GaAs surface of RMS roughness 0.3 nm. The GaAs surface is shown on FIG. 4(b)

For the exemplary non-RTA process, the GaAs layer was etched with citric acid: H₂O₂ (4:1 ratio) etchant for 120 seconds. After GaAs etching, InGaP layer was plasma etched with Cl₂ 15 sccm, Ar 9 sccm, 150 W TCP RF power for 15 seconds. The RMS roughness after the InGaP plasma etch was 0.5 nm, and surface after that step is shown on FIG. 3(a). After plasma etch, the remaining InGaP layer was etched with HCl:H₃PO₄:H₂O (1:1:1 ratio) etchant for 120 seconds, leaving smooth GaAs.

What is claimed is:

1. A method of preserving the surface of a growth substrate after epitaxial lift off, comprising:
providing a growth structure comprising a growth substrate, a sacrificial layer located over the growth substrate, an epilayer located over the sacrificial layer, and at least two protection layers between the growth substrate and the sacrificial layer;
lifting off the epitaxial layer by etching the sacrificial layer;
removing at least one of the protection layers with an etchant chosen from citric acid, H₂O₂, H₃PO₄, NH₄OH, H₂O and combinations thereof; and
removing at least one other protection layer with an etchant chosen from HCl, H₃PO₄, H₂O and combinations thereof.

2. The method of claim 1, further comprising immersing the growth structure in solvent stripper after lifting off the epitaxial layer.

3. The method of claim 2, wherein the solvent stripper is RemoverPG.

4. The method of claim 1, wherein removing one or more of the protection layers further comprises plasma etching.

5. The method of claim 1, wherein the sacrificial layer is etched by immersing the growth structure in HF etchant.

6. The method of claim 5, wherein the HF etchant is agitated by stirring.

7. The method of claim 1, further comprising performing rapid thermal annealing (RTA) on the growth structure subsequent to the lift-off step.

8. The method of claim 7, wherein RTA is performed on the growth structure before removing any of the protection layers.

9. The method of claim 7, wherein RTA is performed on the growth structure after the protection layers are removed.

10. The method of claim 7, wherein RTA is performed on the growth substrate both before and after the protection layers are removed.

11. The method of claim 1, further comprising the following steps after lifting off the epitaxial layer and before removing at least one of the protection layers:
performing RTA on the growth structure;
sonicating the growth structure; and
immersing the growth structure in solvent stripper.

12. The method of claim 11, further applying and removing an adhesive tape from the surface of the growth substrate.

13. The method of claim 1, wherein the growth structure further comprises a buffer layer located between the growth substrate and the protection layers.

14. The method of claim 1, wherein the protection layer nearest the growth substrate comprises InGaP.

15. The method of claim 1, wherein the protection layer furthest from the growth substrate comprises GaAs.

16. The method of claim 14, wherein the growth substrate comprises GaAs and the protection layer furthest from the growth substrate comprises GaAs.

17. The method of claim 15, wherein the etchant for removing the GaAs protection layer is chosen from at least one of H₂O₂, H₃PO₄, NH₄OH, H₂O and combinations thereof.

18. The method of claim 14, wherein the etchant for removing the InGaP protection layer is chosen from at least one of HCl, H₃PO₄, H₂O and combinations thereof.

19. A method of preserving the surface of a growth substrate, comprising
providing a growth structure comprising a growth substrate and at least two protection layers located over the growth substrate;
removing at least one of the protection layers with an etchant chosen from citric acid, H₂O₂, H₃PO₄, NH₄OH, H₂O and combinations thereof; and
removing at least one other protective layer with an etchant chosen from HCl, H₃PO₄, H₂O and combinations thereof.

20. The method of claim 19, further comprising the following steps before removing at least one of the protection layers:
performing RTA on the growth structure;
sonicating the growth structure;
applying and removing adhesive tape from the surface of the growth substrate; and
immersing the growth structure in solvent stripper.

21. The method of claim 19, further comprising the following steps before removing at least one of the protection layers:
immersing the growth structure in solvent stripper;
performing RTA on the growth structure;
sonicating the growth structure;
applying and removing an adhesive tape from the surface of the growth substrate immersing the growth structure in solvent stripper; and
performing another RTA on the growth structure.

22. The method of claim 19, wherein the protection layer located furthest from the growth substrate comprises GaAs and wherein removing the GaAs protection layer comprises etching with an etchant comprising NH₄OH.

23. The method of claim 22, wherein removing the GaAs protection layer further comprises plasma etching.

24. The method of claim 19, wherein the protection layer located nearest the growth substrate comprises InGaP and wherein removing the InGaP protection layer comprises etching with HCl:H2O.

25. The method of claim 19, wherein at least one of the protection layers comprises GaAs, wherein removing the GaAs protection layer comprises etching with NH₄OH:H₂O₂:H₂O, and wherein at least one other protection layer comprises InGaP, wherein removing the InGaP protection layer comprises etching with HCl:H₂O or HCl:H₃PO₄:H₂O.

26. The method of claim 19, wherein at least one of the protection layers comprises GaAs, wherein removing the GaAs protection layer comprises etching with citric acid: H₂O₂, and wherein at least one other protection layer comprises InGaP, wherein removing the InGaP protection layer comprises etching with HCl:H₃PO₄:H₂O or HCl:H₂O.
